(19) United States
(12) Patent Application Publication
(10) Pub. No.: US 2010/0128775 A1
(43) Pub. Date: May 27, 2010

(54) APPARATUS AND METHOD FOR TRANSMITTING SIGNAL IN WIRELESS COMMUNICATION SYSTEM

(75) Inventors: Joon-Hyung KIM, Daejon (KR); Jae-Ho JUNG, Daejon (KR); Gweon-Do JO, Daejon (KR); Kwang-Chun LEE, Daejon (KR)

Correspondence Address: LAHIVE & COCKFIELD, LLP;FLOOR 30, SUITE 3000, ONE POST OFFICE SQUARE, BOSTON, MA, 02109, US

(73) Assignee: Electronics and Telecommunications Research Institute, Daejon (KR)

(21) Appl. No.: 12/624,934

(22) Filed: Nov. 24, 2009

(30) Foreign Application Priority Data
Nov. 24, 2008 (KR) 10-2008-0116915

(51) Int. Cl. H03K 7/08; H04B 1/04

(52) U.S. Cl. 375/238; 455/110

(57) ABSTRACT

Disclosed are an apparatus and method for transmitting a signal in a wireless communication system. The apparatus includes a controller for receiving power control information of a baseband signal, deciding an output mode, and providing an output mode signal, a signal converter for receiving the baseband signal outputting a phase signal, and outputting an envelope signal when the output mode signal indicates a first output mode, a phase modulator for up-converting the phase signal, and an amplifier for combining the envelop signal and the up-converted phase signal for the first output mode and amplifying the combined signal.

### CROSS-REFERENCE TO RELATED APPLICATIONS

The present invention claims priority of Korean Patent Application Nos. 10-2008-0116915, filed on Nov. 24, 2008, which is incorporated herein by reference.

### FIELD OF THE INVENTION

The present invention relates to an apparatus and method for transmitting a signal in a communicating system; and, more particularly, to an apparatus and method for transmitting a signal in a wireless communication system.

### DESCRIPTION OF RELATED ART

In general, a communication system is divided into a wired communication system and a wireless communication system. In the wired communication system, a terminal and a system are connected through a physical cable. Therefore, the wired communication system has serious distance limitation between the terminal and the system due to the physical cable. In the wireless communication system, a wireless terminal and a system are connected through a wireless link established using a predetermined radio frequency (RF).

Therefore, the wireless communication system has relatively less distance limitation between the system and the wireless terminal. Meanwhile, a wired communication system has an advantage of stably providing data at a high speed because the terminal and the system exchange signals through the physical cable in the wired communication system. On the contrary, since a wireless terminal and a system uses radio frequency to exchange a signal there between in a wireless communication system, the wireless communication system transmits data at relatively low speed and has an instability problem.

In order to stably transmit signals in a wireless communication system, various schemes are used between a wireless node and a mobile terminal. For example, a transmission power between a wireless node and a mobile terminal is controlled to stably transmit a signal. Hereinafter, a system and method for controlling a transmission power between a wireless node and a mobile terminal in a wireless communication system will be described.

A transmitter stably transmit a signal in a wireless communication system, various schemes are used between a wireless node and a mobile terminal. For example, a transmission power between a wireless node and a mobile terminal is controlled to stably transmit a signal. Hereafter, a system and a method for controlling a transmission power between a wireless node and a mobile terminal in a wireless communication system will be described.

However, the high efficient switching power amplifier has a disadvantage that linearity is dropped greatly for a non-constant envelope signal having an irregular signal level. Therefore, it is difficult to use a mobile terminal to transmit a signal having the irregular signal level.

A typical transmitter using a switching power amplifier inputs a phase signal to the switching power amplifier using a polar coordinate and applies an envelope signal to a bias terminal of the switching power amplifier. Such a transmitter has been disclosed in U.S. Pat. No. 4,176,319, U.S. Pat. No. 6,529,716, and U.S. Pat. No. 7,400,865. In order to input the phase signal to the switching power amplifier, an analog envelope signal is applied to a bias terminal of a switching power amplifier or an envelope signal is transformed to a digital signal and applied to the switching power amplifier. Such a method was disclosed in Korean Patent Publication No. 10-2006-0038134.

FIGS. 1 and 2 are diagrams illustrating a transmitter for transmitting an envelope signal according to the prior art.

Referring to FIG. 1, the transmitter according to the prior art includes a MODEM 101, a polar converter 102, an analog converter 103, a phase modulator 104, and a switching power amplifier 105.

The MODEM 101 receives a baseband signal and outputs an I(t) signal and a Q(t) signal. The polar converter 102 receives the I(t) signal and the Q(t) signal and outputs a phase signal and an envelope signal. The analog converter 103 converts the envelope signal into an analog signal. The phase modulator 104 up-converts the phase signal into a radio frequency (RF) signal.

As for the analog converter 103, a class-S amplifier, a class-AB amplifier, or an op-amp may be used generally. The switching power amplifier 105 amplifies the up-converted phase signal and outputs a final transmission signal. Such a transmitter according to the prior art does not disadvantageously express an envelope signal smaller than a knee voltage Vknee in a system having an envelope signal abruptly changed, for example, an Orthogonal Frequency Division Multiplexing (OFDM) system because the envelope signal is applied to a bias terminal of the switching power amplifier 105. This is because VDD/VCC for activating the switching power amplifier 105 should be higher than the knee voltage Vknee.

Particularly, an envelope signal has the following properties in an OFDM system. A peak-to-average power ratio is comparatively large such as about 9 to 10 dB, and the peak-to-minimum power ratio is very large such as about 60 dB. Therefore, since the minimum value of the envelope signal is lower than the knee voltage, the minimum value of the envelop signal cannot be expressed due to the limitation of the knee voltage. As a result, AM-AM (amplitude) distortion is caused in an input signal. Therefore, the transmitter of FIG. 1 is proper only for a system having an envelope signal that is not abruptly changed.

In order to overcome the problem, U.S. Pat. No. 6,529,716 discloses a method of selecting one from a plurality of switching power amplifiers according to a power level. However, this method cannot resolve phase discontinuity that is generated when a switching power amplifier performs a switching operation according to a power level.

FIG. 2 is a diagram illustrating a transmitter according to the prior art. The transmitter of FIG. 2 is identical to the transmitter of FIG. 1 in that a polar converter 202 performs polar conversion to up-convert a phase signal and a phase modulator 204 up-converts the phase signal into a radio frequency (RF) signal.

Unlike the transmitter of FIG. 1, the transmitter of FIG. 2 uses a digital converter 203 for converting an envelope signal to a digital signal. Due to the digital converter 203, the envelop signal is outputted in a pulse form having a regular bit sequence. Herein, a delta-sigma modulator is used as the digital converter 203. The envelope signal having the regular pulse form is combined with a phase signal and the switching power amplifier 205 outputs the combined signal. Such a transmitter using the digital converter 203 needs a band pass filter 207 for removing quantization noise that is generated when a bit sequence of the envelope signal is converted.

The transmitter using such a delta-sigma modulator decides noise shaping of quantization noise according to the over-sampling of the envelope signal and the order of the delta-sigma modulator. In case of the 2^{nd} order delta-sigma modulator, the over sampling ratio should be about 16 to 32 for stability of a system. The over sampling ratio denotes a ratio of an amount of in-band noise and an amount of out-band noise that the filter can filter.

The next-generation mobile communication system has wideband characteristics, for example a channel band width of about 20 MHz to 80 MHz for high speed data transmission. When the over sampling ratio of the envelope signal is set to 16, the delta-sigma modulator needs perform high speed sampling such as at a speed of 1.28 GHz which means 80 MHz×16. Therefore, it is difficult to embody it in the form of hardware and power consumption increases due to a high speed digital circuit. As described above, the transmitters shown in FIGS. 1 and 2 have a common problem of limitation in a power control range.

FIG. 3 is a graph showing a bias point of a transistor used in a typical switching power amplifier. The power control range, which is operation range, of the typical switching power amplifier is Vknee to Vmax. Therefore, VDS/VCE should be greater than the knee voltage Vknee in order to enable a transistor of the switching power amplifier to operate in an active region.

In case of the mobile communication terminal system, Vmax is about 3.3V to 3.4V. In case of a bipolar transistor or a CMOS transistor used in a switching power amplifier, a knee voltage is about 0.3 to 0.4V. Therefore, since the transmitters shown in FIGS. 1 and 2 express the envelope signal by converting VDD/VCC, the transmitters of FIGS. 1 and 2 may have limitation of operation range when a small envelope signal is expressed. Eq. 1 shows an operation range of a switching power amplifier in a mobile communication system.

$$Operation range = 10 {log ( \frac{{v}_{max}}{{v}_{knee}} )}^{2} = 10 {log ( \frac{0.4}{0.4} )}^{2} = 18 dB \qquad Eq . 1$$

As shown in Eq. 1, the operation range of the switching power amplifier in the mobile communication system is about 18 dB. On the contrary, the operation range of the typical mobile communication terminal is about 40 to 60 dB. Therefore, there has been a demand to overcome the difference between two operation ranges.

In order to overcome such a problem, Korean Patent Publication No. 10-2008-0063010 discloses a method combined with an out-phasing scheme and an envelope elimination and restoration scheme. Such a method compensates shortcomings of the out-phasing scheme and the EER scheme. This method enables a transmitter to operate in the EER scheme in case of receiving a signal greater than a predetermined thresh hold or to operate in the out-phasing scheme in case of receiving a signal smaller than the predetermined threshold.

However, such a method may be proper to a CDMA system having an envelope signal that is not abruptly changed. However, this method is not proper an OFDM system that has an envelope signal that is abruptly changed. It is because almost data is transmitted based on the out-paging scheme in the OFDM system that has an envelope signal changed abruptly.

### SUMMARY OF THE INVENTION

An embodiment of the present invention is directed to a transmitting apparatus and method that can overcome a power control problem of a mobile communication terminal system according to the prior art.

Another embodiment of the present invention is directed to providing a transmitting apparatus and method for improving quantization noise in a mobile communication terminal system.

Another embodiment of the present invention is directed to providing a transmitting apparatus and method that do not generate phase discontinuity when controlling power.

In accordance with an aspect of the present invention, there is provided a transmitting apparatus including a controller configured to receive power control information of a baseband signal, decide an output mode, and provide an output mode signal, a signal converter configured to receive the baseband signal, output a phase signal, and output an envelope signal when the output mode signal indicates a first output mode, a phase modulator configured to up-convert the phase signal, and an amplifier configured to combine the envelop signal and the up-converted phase signal for the first output mode and amplify the combined signal.

The amplifier may amplify the up-converted phase signal using a knee voltage as a bias voltage when the output mode signal indicates a second output mode.

The controller may include a power controller configured to compare the received power control information with a predetermined threshold value and output mode identification information to identify the first output mode and the second output mode, and a mode selector configured to receive the mode identification information and output the output mode signal.

The signal converter may include a signal generator configured to generate the phase signal and the envelope signal using the received baseband signal, and an envelope signal modulator configured to modulate a pulse width of the envelope signal.

The signal converter may include an envelope signal converter configured to quantize the envelop signal to k-bits.

The transmitting apparatus may further include a DC/DC converter configured to output a DC voltage that is changed according to a voltage control signal received from the controller, and a switch activated by the envelope signal configured to provide the DC voltage value to a bias terminal of the amplifier.

In accordance with another aspect of the present invention, there is provided a method of transmitting a signal in a wireless communication apparatus including deciding an output mode by receiving power control information of a baseband signal, outputting a phase signal by receiving the baseband signal and outputting an envelope signal when the output mode signal indicates a first output mode, up-converting the phase signal, and combining the envelope signal with the up-converted phase signal and amplifying the combined signal in the first output mode.

The method may further include amplifying the up-converted phase signal using a knee voltage as a bias voltage when the output mode signal indicates a second output mode.

Said deciding an output mode may include comparing the received power control information with a predetermined threshold value and outputting mode deification information for identifying the first output mode and the second output mode, and outputting the output mode signal by receiving the mode identification information.

Said outputting a phase signal may include generating the phase signal and the envelope signal using the received baseband signal, and modulating a pulse width of the envelop signal.

The method may further include quantizing the envelop signal into k-bits. The method may further include receiving the power control information and outputting a voltage control signal, outputting a DC voltage value that is changed according to the voltage control signal, and being activated by the envelope signal and providing the DC voltage value to a bias terminal of an amplifier.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

### BRIEF DESCRIPTION OF THE DRAWINGS

FIGS. 1 and 2 illustrate a transmitter for transmitting an envelope signal in accordance with an embodiment of the present invention.

FIG. 3 is a graph showing a bias point of a transistor used in a typical switching power amplifier.

FIG. 4 illustrates an out-phasing scheme used in a transmitter in accordance with an embodiment of the present invention.

FIG. 5 illustrates a transmitter in accordance with an embodiment of the present invention.

FIGS. 6 and 7 are diagrams for describing a dual mode of a transmitting apparatus in accordance with an embodiment of the present invention.

FIG. 8 is a graph showing probability distribution according to a size of an up-link transmission signal of an IMT-advanced system.

FIG. 9 illustrates a pulse width modulator.

FIGS. 10 and 11 are graphs showing characteristics of a signal outputted when an IMT-advanced real signal passes through a transmitting apparatus in accordance with an embodiment of the present invention.

FIG. 12 is a flowchart describing a transmitting method in accordance with another embodiment of the present invention.

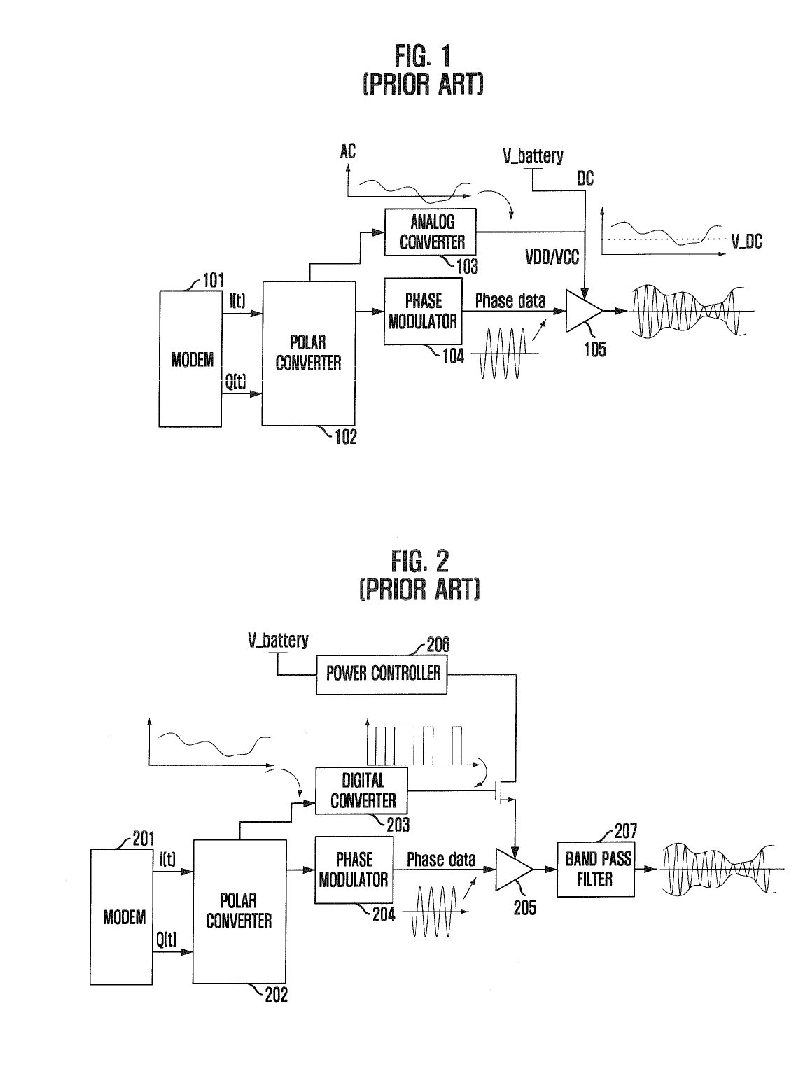

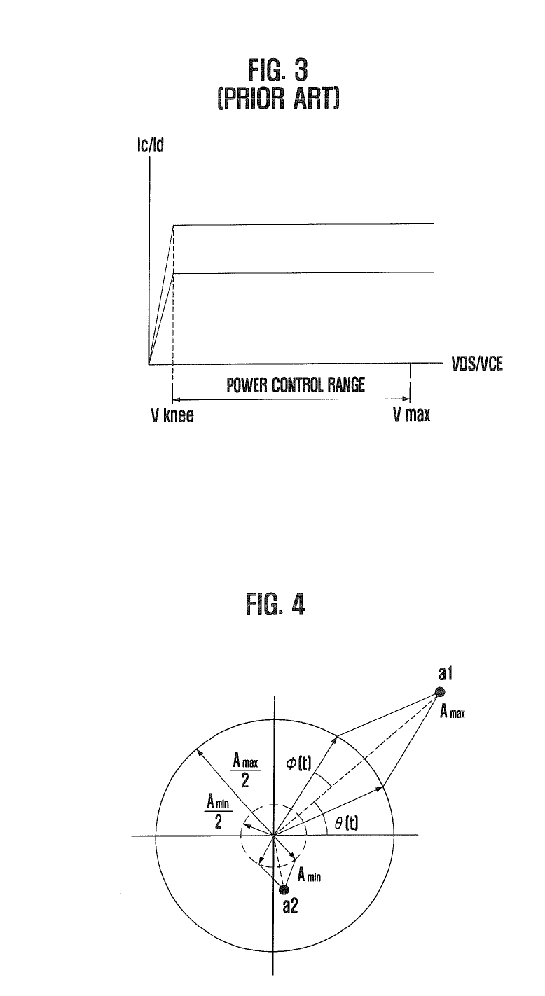

### DESCRIPTION OF SPECIFIC EMBODIMENTS

The advantages, features and aspects of the invention will become apparent from the following description of the embodiments with reference to the accompanying drawings, which is set forth hereinafter.

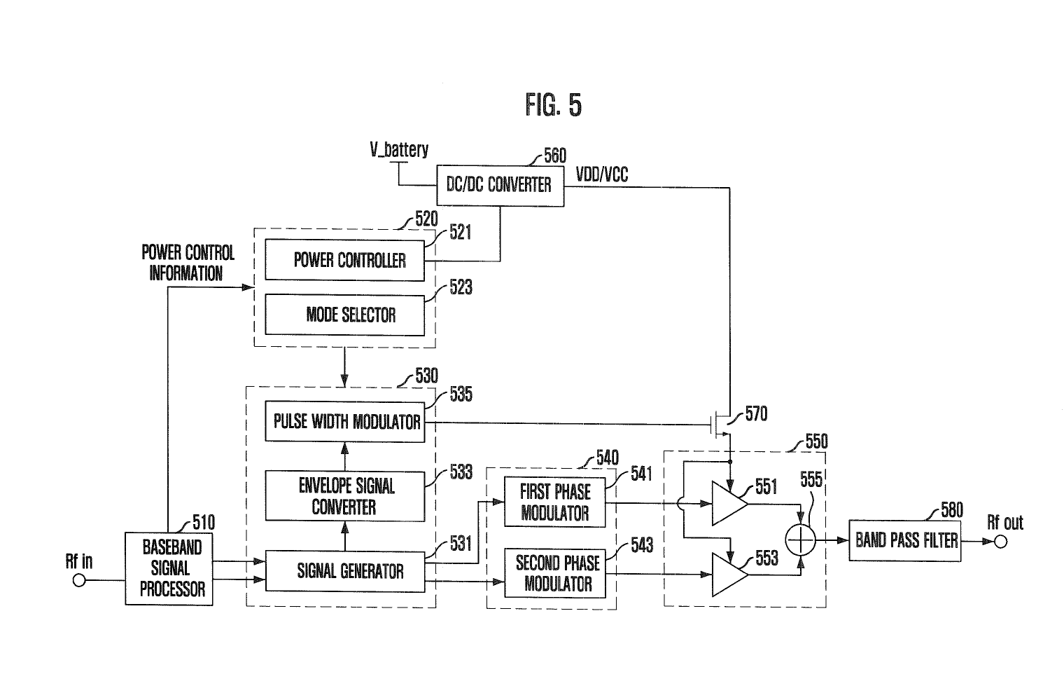

FIG. 5 illustrates a transmitting apparatus in accordance with an embodiment of the present invention.

Referring to FIG. 5, the transmitting apparatus according to the present embodiment includes a controlling unit 520, a signal converting unit 530, a phase modulating unit 540, and an amplifying unit 550.

The baseband signal processor 510 receives a RF signal and outputs power control information. The power control information may be outputted in an analog signal or a digital word. The analog signal may be a pulse density modulation PDM or pulse width modulation (PWM), which is decided by commercial ASCI property of the baseband signal processor 510. Also, the baseband signal processor 510 controls power of a mobile communication terminal according to a location of the mobile communication terminal and an air channel quality state. That is, a low output signal is transmitted when a mobile communication station is close or a channel state is excellent. Or, a high output signal is transmitted when a base station is located at about an edge of a cell or under a bad channel state.

In general, power is controlled using a closed loop method or an open loop method. The mobile communication terminal generally uses the closed loop method that feeding back power control information from a base station. The power control information decided according to a state of a mobile communication terminal is applied to a controlling unit 520 of a baseband signal processor 510. Also, the baseband signal processor 510 transforms the received RF signal into an I(t) signal and a Q(t) signal and outputs the I(t) signal and the Q(t) signal.

The controlling unit 520 receives power control information outputted from the baseband processor 510, decides an output mode, and outputs an output mode signal. Such a controlling unit 520 may include a power controller 521 and a mode selector 523. The power controller 521 receives power control information and compares the received power control information with a predetermined threshold value.

The controlling unit 520 outputs mode identification information according to the comparison result. The mode identification information may be expressed in a 1-bit control signal. Although the mode identification information may be expressed in more bits, it is preferable to express the mode identification information in one bit since the present embodiment includes only two output modes, the first output mode and second output mode. When it is required to control more control modes, for example three modes, it is preferable to express the mode identification information in 2 bits.

The mode identification information is a signal to indicate the first output mode and the second output mode. Hereafter, the first output mode is a high output mode, and the second output mode is a low output mode. The power controller 521 may be embodied using a comparator or a look-up table. When a baseband signal is applied as an analog signal, the power controller 521 may be embodied using an A/D converter. When power control information is an analog signal, a comparator of the power controller 521 may be embodied as an analog circuit. The analog comparator may be embodied in an op-amp.

The power controller 521 decides a DC value applied to switching power amplifiers 551 and 553 according to the output mode. That is, the power controller 521 reads power control information and outputs a voltage control signal according to the read power control information. The voltage control signal is applied to the DC/DC converter 560 to enable the DC/DC converter 560 to output a proper DC value. The DC/DC converter 560 controls power in a high output mode by transforming bias of the switching power amplifiers 551 and 553 up to VDD to Vknee.

That is, the power controller 521 stores look-up tables mapped to resolutions of a mobile communication system in a memory, reads the applied power control information, selects a table value corresponding to the read power control information, and provides the selected table value to the DC/DC converter 560. The DC/DC converter 560 may receive a digital signal or an analog signal. It is decided according to a method of controlling power of a system. The DC/DC converter 560 operates using power from a battery V_battery.

The DC/DC converter 560 receives a voltage control signal from the power controller 521 and outputs a VDD/VCC value to the switching power amplifiers 551 and 553. Such a DC/DC converter 560 may be, included in a transceiver or in a power management block of a mobile communication terminal. When the voltage control signal from the power controller 521 is a digital signal, the DC/DC converter 560 may internally include a decoder having a memory.

The mode selector 523 receives the mode identification information outputted from the power controller 521 and selects an output mode. Then, the mode selector 523 outputs the selected output mode. When the state of the mode identification information is ‘high’, the mode selector 523 outputs a high output mode signal to the signal converting unit 530 for operating in high output mode. When the state of the mode identification information is ‘low’, the mode selector 523 outputs a low output mode signal to the signal converting unit 530 for operating in a low output mode.

The mode selector 523 may include a one-bit comparator. Also, the mode selector 523 may be embodied in a simple switching circuit to control operation of the signal converting unit 530. Furthermore, the mode selector 523 drives a signal generator 531 and a pulse width modulator 535 in the signal converting 530 in a high output mode. As described above, the controlling unit 520 having the power controller 521 and the mode selector 523 decides the high output mode and the low output mode.

The signal converting unit 530 receives a baseband signal and outputs a phase signal. When the output mode signal indicates a high output mode, the signal converting unit 530 outputs an envelope signal. The signal converting unit 530 may include a signal generator 531, an envelope signal converter 533, and a pulse width modulator 535.

The signal generator 531 receives a baseband signal and outputs an out-phased phase signal to the envelope signal converter 533 and the phase modulating unit 540. The phase modulating unit 540 includes a first phase modulator 541 and a second phase modulator 542. The signal generator 531 receives a power control level from the controlling unit 520 and calculates Φ(t) by normalizing A(t) properly to the received power control level. When the signal generator 531 receives an output mode signal indicating a high output mode from the mode selector 523, the signal generator 531 outputs an envelope signal.

A typical out-phasing scheme according to the prior art deteriorates efficiency since the typical output-phasing scheme causes unnecessary power consumption in a system where a size of an input signal is changed abruptly. However, the signal generator 531 according to the present embodiment uses a method shown in FIG. 4 to generate the out-phased phase signal unlike the typical out-phasing scheme according to the prior art.

FIG. 4 illustrates an out-phasing scheme used in a transmitter according to an embodiment of the present invention. As shown in FIG. 4, the out-phasing scheme according to the present embodiment changes a value of Aₘₐₓ according to a size of the envelope signal. Herein, the value of Aₘₐₓ decides an output boundary. In FIG. 4, ‘a1’denotes an envelope signal having a value of Aₘₐₓ. The envelope signal ‘a1’ is expressed as the sum of two vectors Aₘₐₓ/2. ‘a2’ denotes an envelope signal having the value of Aₘᵢₙ. The envelope signal ‘a2’ is expressed as the sum of two vectors Aₘᵢₙ/2. Eq. 2 shows ‘a1’ and ‘a2’.

$${S}_{1} ( t ) = \frac{{A}_{N} ( t )}{2} cos ( {w}_{c} t + θ ( t ) + φ ( t ) ) \\ {S}_{2} ( t ) = \frac{{A}_{N} ( t )}{2} cos ( {w}_{c} t + θ ( t ) - φ ( t ) ) \\ φ ( t ) = {cos}^{- 1} ( \frac{A ( t )}{{A}_{N} ( t )} ) \\ S ( t ) = {S}_{1} ( t ) + {S}_{2} ( t ) \qquad Eq . 2$$

In Eq. 2, A_{N}(t) is changed from Aₘᵢₙ to Aₘₐₓ according to a size of an input envelope signal. If Aₘᵢₙ can express the minimum size signal, A_{N}(t) can have the ideal characteristics of an envelope signal. The out-phasing scheme according to the present embodiment has excellent efficiency because the output-phasing scheme according to the present embodiment inputs only a phase signal with a uniform out-phased size to the switching power amplifiers 551 and 553.

However, When the outputted A_{N}(t) is inputted to the power amplifiers 551 and 553, power is not controlled like a typical transmitter. Therefore, an output boundary is divided into two modes in the present embodiment. In case of a high output mode, A_{N}(t) of an envelope signal outputted by the out-phasing scheme is passed through the pulse width modulator 535, the high efficiency characteristics maintain, and an operation range extends to the knee voltage Vₖₙₑₑ.

In a low output mode that amplifies a signal having a lower size than a knee voltage, the out-phasing scheme is used. In more detail, the bias terminals of the switching power amplifiers 551 and 553 are fixed to the knee voltage in the low output mode. Eq. 3 shows the out-phasing scheme for the low output mode.

$${S}_{1} ( t ) = {V}_{knee} cos ( {w}_{c} t + θ ( t ) + φ ( t ) ) \\ {S}_{2} ( t ) = {V}_{knee} cos ( {w}_{c} t + θ ( t ) - φ ( t ) ) \\ φ ( t ) = {cos}^{- 1} ( \frac{A ( t )}{2 {V}_{knee}} ) \\ S ( t ) = {S}_{1} ( t ) + {S}_{2} ( t ) \qquad Eq . 3$$

In Eq. 3, S₁(t) and S₂(t) can be expressed for A(t) having a small value using φ(t). Therefore, S(t) can be expressed even in a small power control range.

Meanwhile, the signal generator 531 outputs an out-phased envelope signal in the high output mode. Since the outputted out-phased envelop signal is an envelope signal of an original signal, the size of the envelop signal is changed abruptly. Thus, when the outputted envelope signal is inputted to the pulse width modulator 535 as it is, a quantization of the pulse width modulator 535 generates more quantization noise. Such a quantization noise is equivalent to a function of a difference between the maximum value and the minimum value of an envelope signal. That is, when the difference between the maximum value and the minimum value is small, the quantization noise becomes smaller.

The envelope signal converter 533 receives an envelope signal from the signal generator 531, decides a maximum size and a minimum size of an envelope signal, and quantizes the envelope signal to k-bits. That is, the difference between the maximum value and the minimum value is reduced by setting the minimum value of the envelope signal to a predetermined value R.

Herein, when the minimum value of the envelope signal increases to a predetermined value, a signal becomes distorted. However, output signals of the switching power amplifiers 551 and 553 can be restored to original signals by converting a phase signal φ(t) through cos⁻¹(A(t)/R) using the out-phasing scheme according to the present embodiment. The method according to the present embodiment can reduce the quantization noise by reducing a range of the maximum and minimum values of the envelope signal applied to the pulse width modulator 535 within a range not deteriorating the efficiency of a system. Herein, the minimum value can depend on the characteristics of the envelope signal.

Hereafter, an IMT-advanced system where a transmitter according to an embodiment of the present invention is applied thereto will be described.

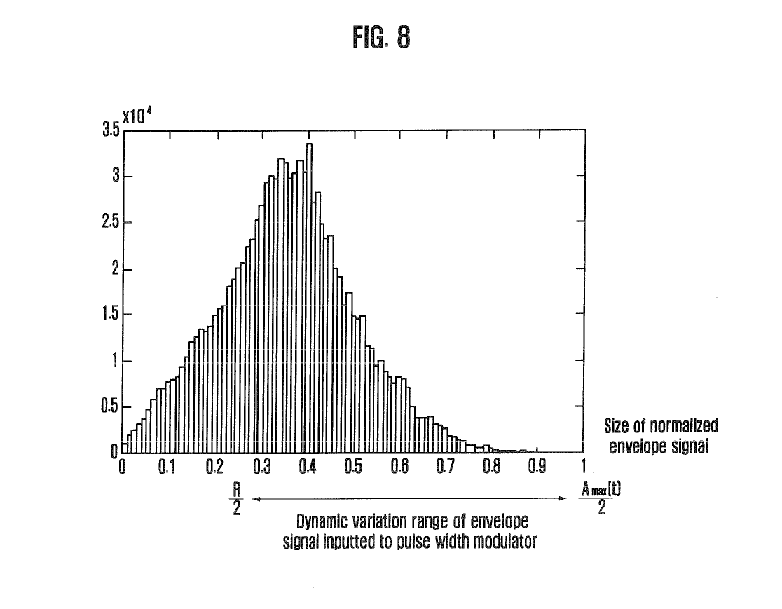

FIG. 8 is a graph showing probabilistic distribution according to a size of an up-link transmission signal of an IMT-advanced system.

As shown in the graph of FIG. 8, a peak-to-average value is about 9 to 10 dB and a range of peak-to-minimum value is about 50 to 60 dB. When the minimum value R is set to close to a peak value, a dynamic range of the envelope signal applied to the pulse width modulator becomes reduced, thereby reducing quantization noise. When an envelope signal is smaller than the minimum value R, the switching power amplifier should amplify the envelope signal as much as R/2. Thus, system efficiency is deteriorated.

That is, it is important to decide an optimized R value that minimizes the quantization noise without reducing the system efficiency. When a value R is set within a range smaller than the peak signal as much as about 12 dB and larger than an average signal as much as about 2 to 3 dB, it is possible to improve the quantization noise more than 3 dB while reducing the system efficiency within about 1%. It is because the number of data of a small signal is significantly larger than the number of overall data on the probabilistic distribution of the envelop signal.

Hereinbefore, although the method of deciding a value R was described based on the IMT-advanced system, the method of deciding a value R is not limited to the IMT-advanced system. It will be applied to various systems identically. Particularly, it may effectively reduce quantization noise in a CDMA system or an EDGE system having not high peak to average value.

The pulse width modulator 535 receives a quantized envelope signal (k-bits) and outputs a bit sequence having ‘1’s and ‘0’s. The pulse width modulator 535 may be embodied as digital hardware and analog hardware. For example, the pulse width modulator. 535 may be embodied in a digital circuit such as ASCI. When the pulse width modulator 535 is embodied in analog hardware, the envelope signal is converted from a digital signal to an analog signal and inputted to the pulse width modulator 535.

Meanwhile, a high state of 1-bit signal outputted from the pulse width modulator 535 is mapped to VDD/VCC, a bias level of the switching power amplifiers 551 and 553. A low state of 1-bit signal is mapped to ‘0’. Therefore, it is possible to reduce VDD/VCC value according to an output level. The pulse width modulator 535 is used to express the out-phased, level width limited, and quantized envelop signal in 1-bit. Therefore, the present invention is not limited to the pulse width modulator 535. For example, a delta-sigma modulator may be used instead of the pulse width modulator 535. Also, all kinds of digital/analog circuits that express an envelope signal in 1-bit can be used.

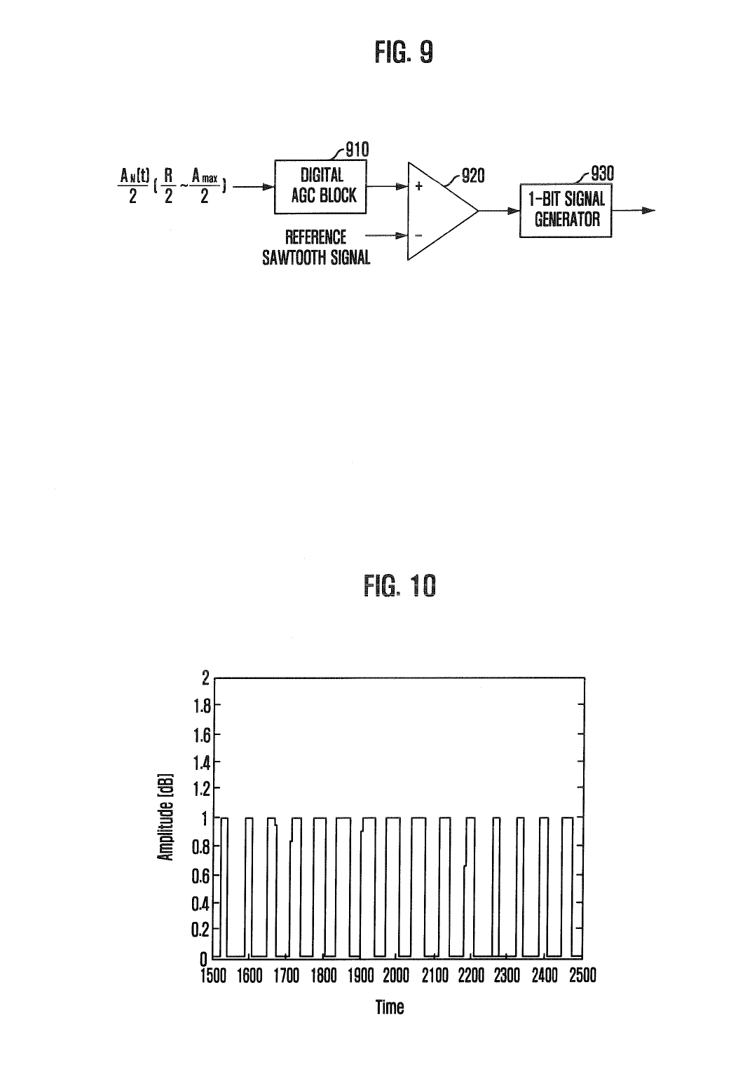

FIG. 9 is a diagram illustrating a pulse width modulator 535.

Referring to FIG. 9, the pulse width modulator 535 includes a digital auto gain control (AGC) block 910, a comparator 920, and a 1-bit signal generator 930. The digital AGC block 910 reduces an error for a dynamic range of the pulse width modulator 535. Also, the digital AGC block 910 makes the maximum size of the envelop signal inputted to the comparator to be identical to the maximum size of a reference saw tooth waveform. The comparator 920 compares a signal outputted from the digital AGC block 910 with the reference sawtooth signal.

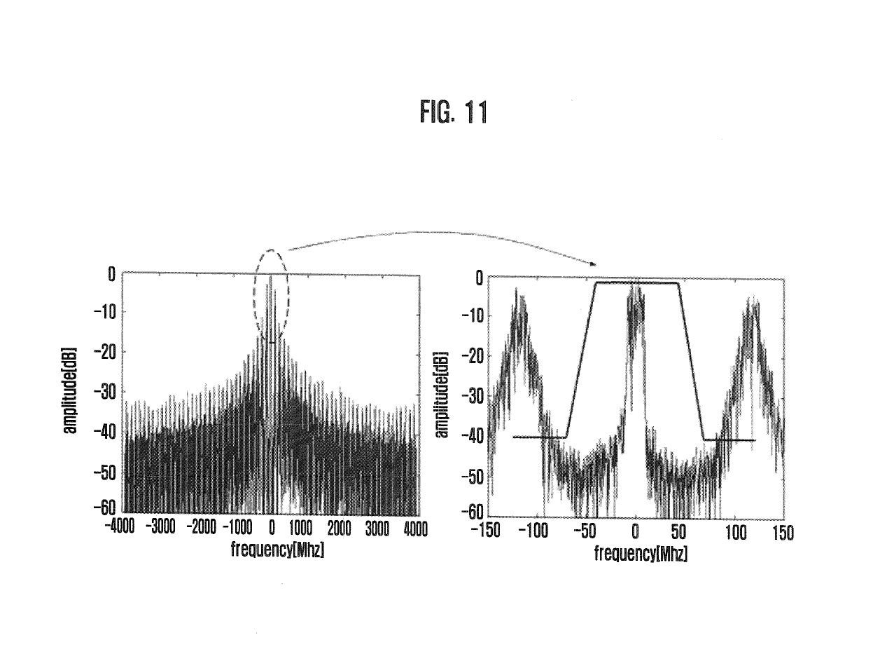

The 1-bit signal generator 930 receives a signal outputted from the comparator 920 and generates a 1-bit signal. The pulse width modulator 535 compares a size of an envelope signal A_{N}(t)/2 and a reference sawtooth signal (or a random sawtooth waveform and a triangle waveform). When the envelope signal is greater than the reference signal, the pulse width modulator 535 outputs ‘1’. On the contrary, when the envelope signal is smaller than the reference signal, the pulse width modulator 535 outputs ‘0’. FIGS. 10 and 11 show the outputs of the pulse width modulator 535.

FIGS. 10 and 11 are graphs showing characteristics of output signals generated by processing an IMT-advanced real signal through the signal generator 531, the envelope signal converter 533, and the pulse width modulator 535. FIG. 10 is a time domain graph and FIG. 11 is a frequency domain graph.

The phase modulating unit 540 receives the out-phased phase signal from the signal converting unit 530 and up-converts the received phase signal. The phase signal may be up-converted through various known methods. For example, an up-converter may be used to convert the phase signal is to an analog signal in case of digital-to-analog conversion. In this case, the phase modulating unit 540 may be embodied in a typical quadrature modulator. In case of an intermediate frequency (IF) signal, an up-mixer may be used for digital-to-analog conversion.

Meanwhile, the phase modulating unit 540 may be embodied using a phase shifter. The modulated phase signal is outputted in a form of a voltage or a digital word. In case of using a phase modulator, the digital-to-analog conversion is not advantageously used. However, when a bandwidth of a phase signal is large, that is, the modulation of the phase signal changes quickly, a desired phase signal may be not disadvantageously outputted by time delay characteristics of a phase shifter.

Therefore, it is preferable to use a phase modulator for a system having a low sampling speed and a narrow band width, for example, a CDMA system, a GSM system, an EDGE signal, and a WCDMA system. On the contrary, it is preferable to use an up-converter using digital-to-analog conversion for a system having a high sampling speed and wideband width, for example, an IMT-advanced system, a WiMAX system, a WiBro system, and a WLAN system.

However, the present invention is not limited thereto. That is, one of the phase modulator and the up-modulator using digital-to-analog conversion may be selected according to corresponding application.

The amplifying unit 550 combines the envelope signal with the up-converted phase signal and amplifies the combined signal in the high output mode. The amplifying unit 550 amplifies the up-converted phase signal using the knee voltage as a bias voltage in the low output mode. The amplifying unit 550 may include switching power amplifiers 551 and 553 and a RF combiner 555. The envelope signal having a ‘1’ state or a ‘0’ state is applied to the switching power amplifiers 551 and 553. The switching power amplifiers 551 and 553 combines a phase signal and an envelope signal, amplify the combined signal, and output the amplified signal to the RF combiner 555. The RF combiner 555 combines two out-phased signals applied through two paths.

Although it is not shown in FIG. 5, a phase signal is multiplied with a 1-bit signal, the multiplied phase signal is up-converted, and the up-converted signal is applied to the switching power amplifiers 551 and 553 as a method for applying the quantized envelop signal to the switching power amplifiers 551 and 553 of the amplifying unit 550. In this method, an overall circuit becomes simpler because the switching power amplifiers 551 and 553 are interfaced with the DC/DC converter 560. In case of using the phase modulator, an On/Off switch is included to express a 1-bit envelope signal at an output sing of the phase modulator. The envelop signal is multiplied with the phase signal. The multiplied signal is inputted to the switching power amplifiers 551 and 553.

The bans pass filter 580 filters harmonic components of the amplified signal outputted from the amplifying unit 550. The filtered output signal is transferred to an antenna end. The cut-off characteristics of the band pass filter 580 are decided according to a cycle of a reference signal of the pulse width modulator 535. It is because the harmonic components of the final output signal are generated from high order frequency of a cycle of a reference signal of the pulse width modulator 535.

The transmitter according to the present invention advantageously has 100% efficiency because the transmitter according to the present invention operates in a dual mode based on power control information of a baseband signal. Also, the transmitter according to the present invention advantageously improves quantization noise by limiting a difference between a peak and a minimum value of the envelope signal.

Furthermore, the transmitter according to the present embodiment uses the out-phasing scheme for overcoming the limitation of the power control range in the low output mode. Therefore, the transmitter according to the present embodiment does not have the limitation of the dynamic range. Since phase discontinuity problem is not generated, the power control method is simple and it requires not additional hardware or software element for compensating phase discontinuity.

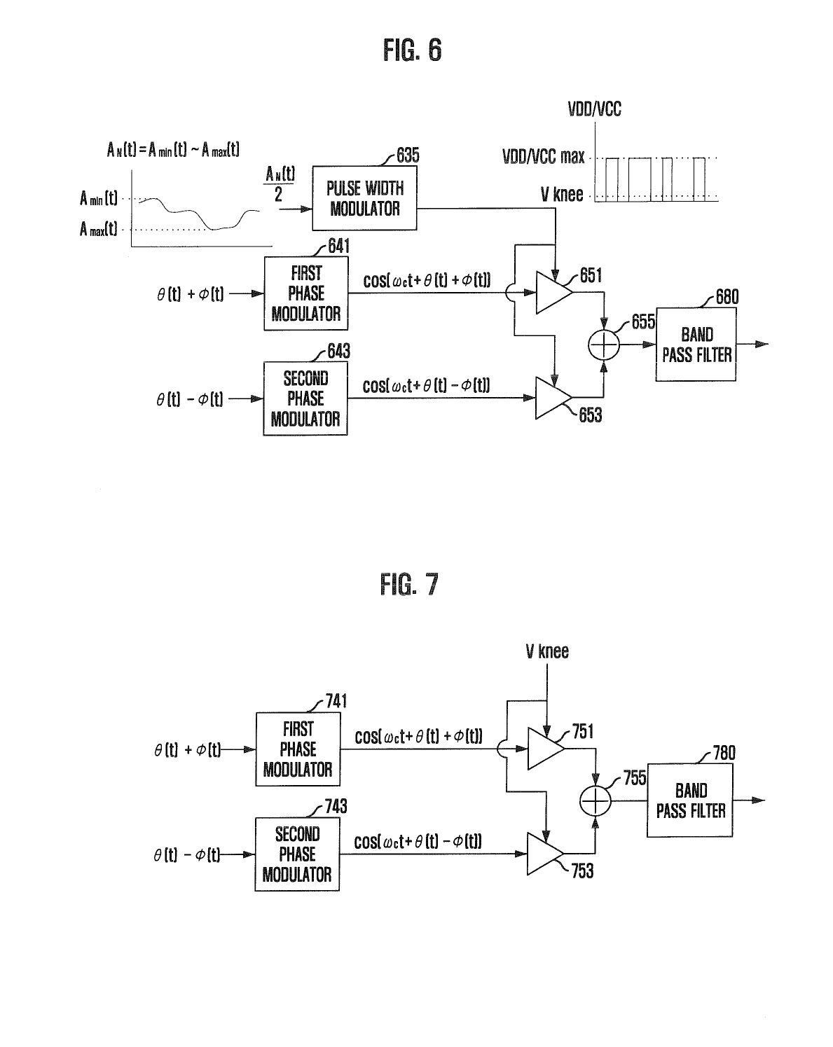

FIGS. 6 and 7 illustrate a dual mode of a transmitter in accordance with an embodiment of the present invention.

Referring to FIG. 6, modulated phase signals (cos(ω_{c}t+θ(t)+φ(t)), cos(ω_{c}t+θ(t)−φ(t))) from a first phase modulator 641 and a second phase modulator 642 are inputted to the switching power amplifiers 651 and 653. Also, the out-phased envelop signal A_{N}(t)/2 is inputted to bias terminals of the switching power amplifiers 651 and 653 through a 1-bit quantizer of the pulse width modulator 635. The output signal s(t) of the switching power amplifiers 651 and 653 is applied to the band pass filter 680 through the RF combiner 655 that expresses a sum of vectors.

Meanwhile, referring to FIG. 7, modulated phase signals (cos(ω_{c}t+θ(t)+φ(t)), cos(ω_{c}t+θ(t)−φ(t))) from a first phase modulator 741 and a second phase modulator 742 are inputted to the switching power amplifiers 751 and 753. The switching power amplifiers 751 and 753 do not operate when VDD/VCC decreases below the knee voltage Vknee in the low output mode. Herein, the bias voltages of the switching power amplifiers 751 and 753 are fixed to the knee voltage and the typical out-phasing scheme is used, thereby outputting a desired signal. The output signal of the switching power amplifiers 751 and 753 is applied to the band pass filter 780 through the RF combiner 755 that expresses a sum of vectors.

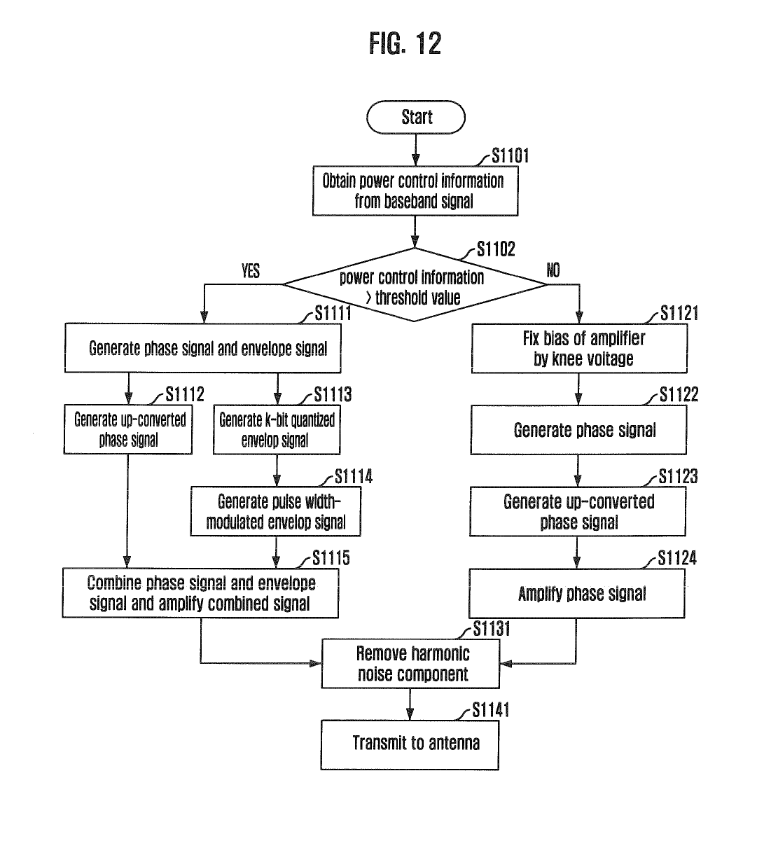

FIG. 12 is a flowchart illustrating a transmitting method in accordance with an embodiment of the present invention.

Referring to FIG. 12, power control information is obtained from a baseband signal at step S1101. The power control information is outputted in an analog signal or a digital word. It is decided by the ASCI characteristics.

The obtained power control information is compared with a predetermined threshold value at step S1102. A typical comparator or a look-up table may be used for comparing the obtained power control information with the predetermined threshold value. When a baseband signal is applied as an analog signal, an A/D converter may be used to compare the power control information with the predetermined threshold value. The output mode is decided according to the comparison result.

In case of the high output mode, an out-phased phase signal and an envelope signal are generated from the baseband signal at step S1111. Since the method of outputting the out-phased phase signal was described in reference with FIG. 4 and Eq. 2, the detail description thereof is omitted. The phase signal is up-converted using an up converter including digital-to-analog conversion or a phase modulator at step S1112. The envelop signal is quantized to k-bits at step S1113 and modulated in a pulse width at step S1114. Then, the up-converted phase signal is combined with the modulated envelope signal and the combined signal is amplified at step S1115.

Meanwhile, when the power control information is smaller than the threshold value, the transmitter operates in the low output mode. The low output mode means that the input signal is lower than the knee voltage. A typical out-phasing scheme is used in the low output mode that amplifies a signal. In the low output mode, a bias terminal of the amplifier is fixed to the knee voltage at step S1121. Therefore, the output signal is expressed like Eq. 3. Then, the out-phased phase signal is generated from a baseband signal at step S1122 and the generated phase signal is up-converted at step S1123. The up-converted phase signal is amplified at step S1124.

Harmonic component of a signal S(t) outputted in the high output mode or the low output mode is eliminated through filtering at step S1131 and the filtered output signal is transmitted to an antenna at step S1141.

The above described method according to the present invention can be embodied as a program and stored on a computer readable recording medium. The computer readable recording medium is any data storage device that can store data which can be thereafter read by the computer system. The computer readable recording medium includes a read-only memory (ROM), a random-access memory (RAM), a CD-ROM, a floppy disk, a hard disk and a magneto-optical disk.

An apparatus of transmitting a signal in a wireless communication system according to an embodiment of the present invention can resolve a power control program of a mobile communication terminal system according to the prior art. Also, the apparatus can improve quantization noise in the mobile communication terminal system. Further, a phase discontinuity problem is not occurred when power is controlled.

What is claimed is:

1. A transmitting apparatus, comprising:
a controller configured to receive power control information of a baseband signal, decide an output mode, and provide an output mode signal;
a signal converter configured to receive the baseband signal, output a phase signal, and output an envelope signal when the output mode signal indicates a first output mode;
a phase modulator configured to up-convert the phase signal; and
an amplifier configured to combine the envelop signal and the up-converted phase signal for the first output mode and amplify the combined signal.

2. The transmitting apparatus of claim 1, wherein the amplifier amplifies the up-converted phase signal using a knee voltage as a bias voltage when the output mode signal indicates a second output mode.

3. The transmitting apparatus of claim 1, wherein the controller includes:
a power controller configured to compare the received power control information with a predetermined threshold value and output mode identification information to identify the first output mode and the second output mode; and
a mode selector configured to receive the mode identification information and output the output mode signal.

4. The transmitting apparatus of claim 1, wherein the signal converter includes:
a signal generator configured to generate the phase signal and the envelope signal using the received baseband signal; and
an envelope signal modulator configured to modulate a pulse width of the envelope signal.

5. The transmitting apparatus of claim 4, wherein the signal converter includes an envelope signal converter configured to quantize the envelop signal to k-bits.

6. The transmitting apparatus of claim 1, further comprising:
a direct current (DC)/DC converter configured to output a DC voltage that is changed according to a voltage control signal received from the controller; and
a switch activated by the envelope signal configured to provide the DC voltage value to a bias terminal of the amplifier.

7. A method of transmitting a signal in a wireless communication apparatus, comprising:
deciding an output mode by receiving power control information of a baseband signal;
outputting a phase signal by receiving the baseband signal and outputting an envelope signal when the output mode signal indicates a first output mode;
up-converting the phase signal; and
combining the envelope signal with the up-converted phase signal and amplifying the combined signal in the first output mode.

8. The method of claim 7, further comprising:
amplifying the up-converted phase signal using a knee voltage as a bias voltage when the output mode signal indicates a second output mode.

9. The method of claim 7, wherein said deciding an output mode includes:
comparing the received power control information with a predetermined threshold value and outputting mode deification information for identifying the first output mode and the second output mode; and
outputting the output mode signal by receiving the mode identification information.

10. The method of claim 7, wherein said outputting a phase signal includes:
generating the phase signal and the envelope signal using the received baseband signal; and
modulating a pulse width of the envelop signal.

11. The method of claim 10, further comprising:
quantizing the envelop signal into k bits.

12. The method of claim 7, further comprising:
receiving the power control information and outputting a voltage control signal;
outputting a DC voltage value that is changed according to the voltage control signal; and
being activated by the envelope signal and providing the DC voltage value to a bias terminal of an amplifier.
